(19) United States
(12) Patent Application Publication
(10) Pub. No.: US 2017/0069835 A1
(43) Pub. Date: Mar. 9, 2017

(54) METHOD OF MANUFACTURING MAGNETORESISTIVE MEMORY DEVICE

(71) Applicants: KABUSHIKI KAISHA TOSHIBA, Tokyo (JP); SK HYNIX INC., Icheon-si (KR)

(72) Inventors: Yasuyuki SONODA, Seoul (KR); Min Suk LEE, Seongnam-si (KR); Chang Hyup SHIN, Yongin-si (KR); Ji Hwan HWANG, Seoul (KR)

(73) Assignees: KABUSHIKI KAISHA TOSHIBA, Tokyo (JP); SK HYNIX INC., Icheon-si (KR)

(21) Appl. No.: 15/065,826

(22) Filed: Mar. 9, 2016

Related U.S. Application Data
(60) Provisional application No. 62/216,209, filed on Sep. 9, 2015.

(51) Int. Cl. H01L 43/12; H01L 43/08

(52) U.S. Cl. CPC H01L 43/12; H01L 43/08

(57) ABSTRACT

According to one embodiment, a method of manufacturing a magnetoresistive memory device includes forming a base substrate including a conductive electrode exposed at a part of a surface, forming a stacked layer structure for a magnetoresistive element on the base substrate, processing the stacked layer structure by etching and thereby forming the magnetoresistive element on the electrode, and exposing the magnetoresistive element to an atmosphere of oxygen radicals.

### CROSS-REFERENCE TO RELATED APPLICATIONS

This application claims the benefit of U.S. Provisional Application No. 62/216,209, filed Sep. 9, 2015, the entire contents of which are incorporated herein by reference.

### FIELD

Embodiments described herein relate generally to a method of manufacturing a magnetoresistive memory device.

### BACKGROUND

Recently, large-capacity magnetoresistive random access memories (MRAMs) using magnetic tunnel junction (MTJ) elements have been gaining attention and raising expectations. The MTJ element comprises two magnetic layers sandwiching a tunnel barrier layer: a magnetization fixed layer (reference layer) having a fixed direction of magnetization and a magnetization free layer (storage layer) having an easily reversible direction of magnetization.

### BRIEF DESCRIPTION OF THE DRAWINGS

FIG. 1 is an equivalent circuit diagram showing a memory cell array of an MRAM of a first embodiment.

FIG. 2 is a cross-sectional diagram showing the structure of a memory cell portion of the MRAM of FIG. 1.

FIGS. 3A to 3F are cross-sectional diagrams showing the manufacturing procedure of the memory cell portion of the MRAM of FIG. 1.

FIG. 4 is an overview configuration diagram showing an oxidation process unit of the first embodiment.

FIG. 5 is a diagram showing the distribution of SFRs in a wafer.

FIGS. 6A and 6B are cross-sectional diagrams showing the manufacturing procedure of a magnetoresistive memory device of a second embodiment.

FIGS. 7A and 7B are cross-sectional diagrams showing the manufacturing procedure of a magnetoresistive memory device of a third embodiment.

### DETAILED DESCRIPTION

In general, according to one embodiment, a method of manufacturing a magnetoresistive memory device comprises: forming a base substrate including a conductive electrode exposed at a part of a surface; forming a stacked layer structure on the base substrate; processing the stacked layer structure by etching and thereby forming the magnetoresistive element on the electrode; and exposing the magnetoresistive element to an atmosphere of oxygen radicals.

Embodiments will be described hereinafter with reference to the accompanying drawings.

### First Embodiment

FIG. 1 is an equivalent circuit diagram showing a memory cell array and peripheral circuits of a magnetoresistive memory device (MRAM) of the first embodiment.

A memory cell in a memory cell array MA comprises an MTJ element as a magnetoresistive memory element and a switch element (for example, a field-effect transistor [FET]) T connected to each other in series. One end of the series-connected entity (one end of the MTJ element) is electrically connected to a bit line BL, and the other end of the series-connected entity (one end of the switch element T) is electrically connected to a source line SL.

The control terminal of the switch element, for example, the gate electrode of an FET is electrically connected to a word line WL. The potential of the word line WL is controlled by a first control circuit 1. Further, the potentials of the bit line BL and the source line SL are controlled by a second control circuit 2.

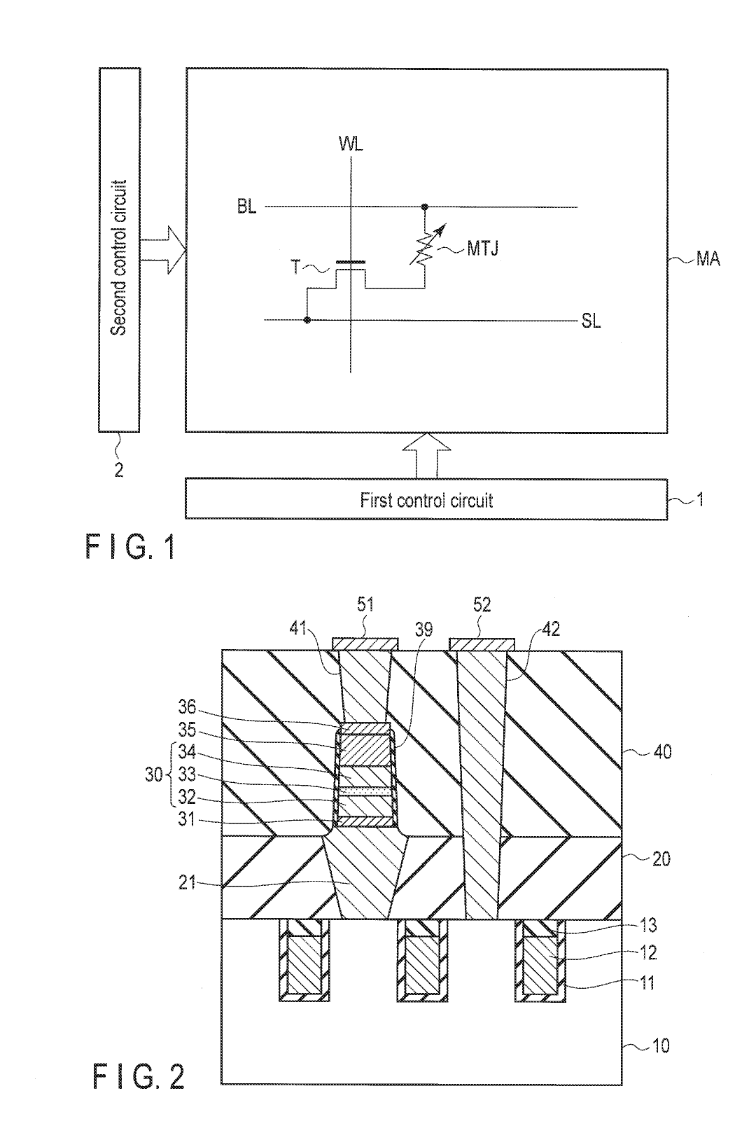

FIG. 2 is a cross-sectional diagram showing the structure of the memory cell portion of the MRAM of FIG. 1.

A MOS transistor as a switch is formed on the surface of an Si substrate 10, and a first interlayer insulating film 20 of SiO₂ or the like is formed thereon. The transistor has a buried gate structure in which a gate electrode 12 is formed in such a manner as to be buried in a groove provided in the Si substrate 10 via a gate insulating film 11. The gate electrode 12 is formed in such a manner as to fill the groove halfway, and a protective insulating film 13 of SiN or the like is then formed thereon. Further, although not shown in the drawing, p- and n-type impurities are scattered respectively on the sides of the buried gate structure to form a source and drain region.

Note that the structure of the transistor is not necessarily limited to the buried gate structure. For example, it is also possible to form a gate electrode on the surface of the Si substrate 10 via a gate insulating film. It suffices that the transistor portion is configured to function as a switch element.

The interlayer insulating film 20 is provided with a contact hole to connect to the drain of the transistor, and a bottom electrode (BEC) 21 is formed in such a manner as to be buried in the contact hole. The bottom electrode 21 can be formed of a conductive material such as W, Ta, Ru, Ti, TaN or TiN.

On a part of the bottom electrode 21, a buffer layer 31 is formed. The buffer layer 31 contains, for examples, Al, Be, Mg, Ca, Hf, Sr, Ba, Sc, Y, La, Zr, Si, Hf, W, Cr, Mo, Nb, Ti, Ta or V. Moreover, the buffer layer may also include a boride of any of these. The boride is not limited to a binary compound consisting of two kinds of elements but it may be also a ternary compound consisting of three kinds of elements. In other words, the material may be a mixture of binary compounds. For example, HfB, MgAlB, HfAlB, ScAlB, ScHfB, HfMgB may be used. Furthermore, the above-described material may be stacked.

With use of a metal having a high melting point and a boride thereof, the diffusion of the material of the buffer layer to the magnetic layer can be suppressed, thereby making it possible to prevent the deterioration of the MR ratio. Here, metals having a high melting point are those having a melting point higher than those of Fe and Co, which are, for example, Zr, Hf, W, Cr, Mo, Nb, Ti, Ta, and V.

On the buffer layer 31, a storage layer (first magnetic layer) 32 of CoFeB as a ferromagnetic magnetization free layer, a tunnel barrier layer (nonmagnetic layer) 33 of MgO, a reference layer (second magnetic layer) 34 of CoPt as a ferromagnetic magnetization fixed layer are formed. That is, an MTJ element 30 in which the tunnel barrier layer 33 is sandwiched between the two ferromagnetic layers 32 and 34 is formed.

A shift-adjustment layer 35 of CoPt, CoPd, CoNi or the like is formed on the MTJ element 30, and a cap layer 36 of Ta, Ru, Pt, W or the like is then formed thereon. The MTJ element portion including the MTJ element 30 forms an upward convex. On the sidewall of the MTJ element portion, a sidewall insulating film 39 is formed.

Note that the buffer layer 31 is provided to encourage crystallization of the layers formed thereon. The buffer layer 31 may be omitted in a case where the layers are sufficiently crystallized without the buffer layer. The storage layer can be formed of magnetic material such as CoFeB or FeB. The reference layer can be formed of magnetic material such as CoPt, CoNi or CoPd. Further, the sidewall insulating film 39 is a layer of materials redeposited in an MTJ etching process including the material composing the bottom electrode 21 and, more specifically, mainly consists of an oxide film of the material composing the bottom electrode 21.

On the substrate provided with the MTJ element portion, a second interlayer insulating film 40 of SiO₂ or the like is formed. In the interlayer insulating film 40, a contact plug (top electrode [TEC]) 41 is buried to connect to a cap layer 36 formed on the MTJ element 30. Further, a contact plug 42 is buried in the interlayer insulating film 40 and the interlayer insulating film 20 to connect to the source of the transistor portion. On the interlayer insulating film 40, an interconnect (BL) 51 which connects to the top electrode 41 and an interconnect (SL) 52 which connects to the contact plug 42 are formed. The contact plug 41, 42 can be formed of a conductive material such as W, Ta, Ti, TaN or TiN.

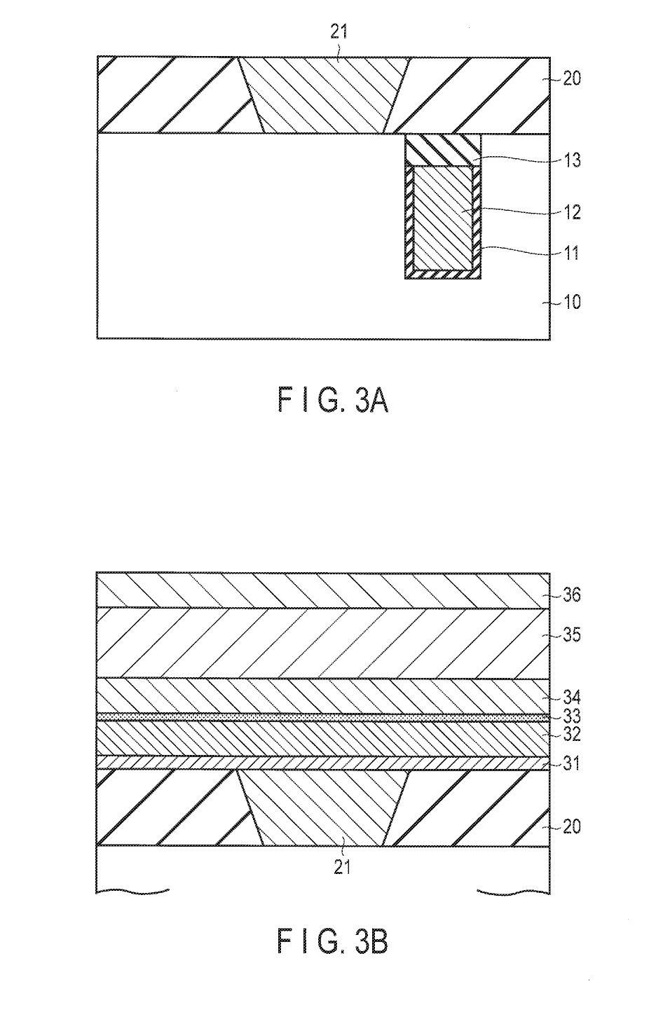

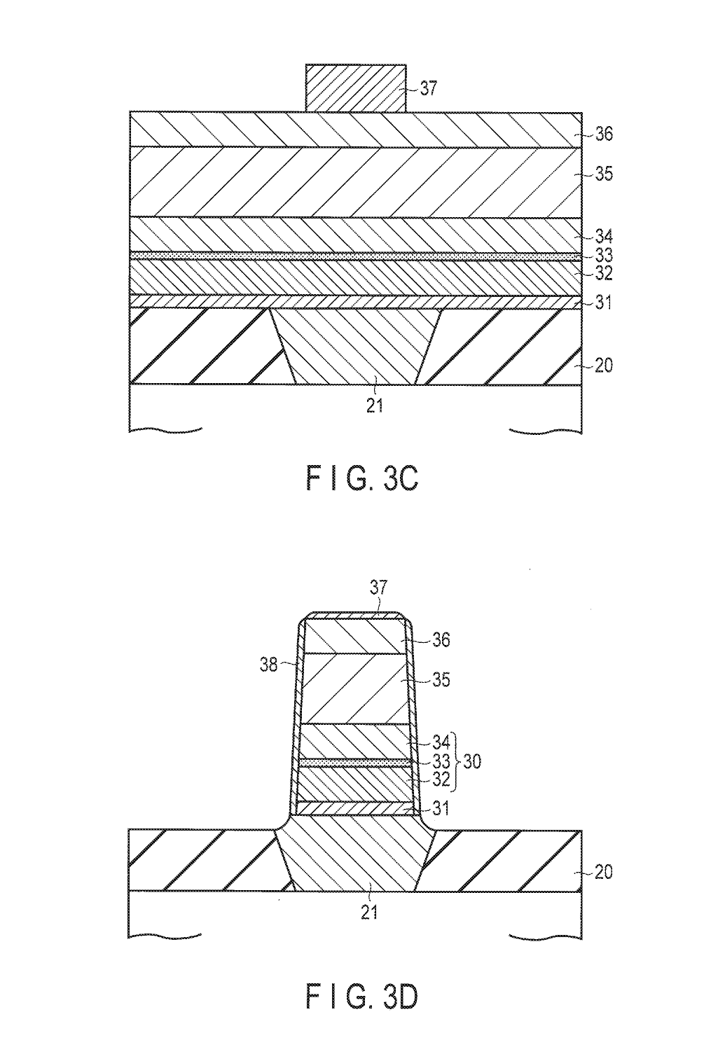

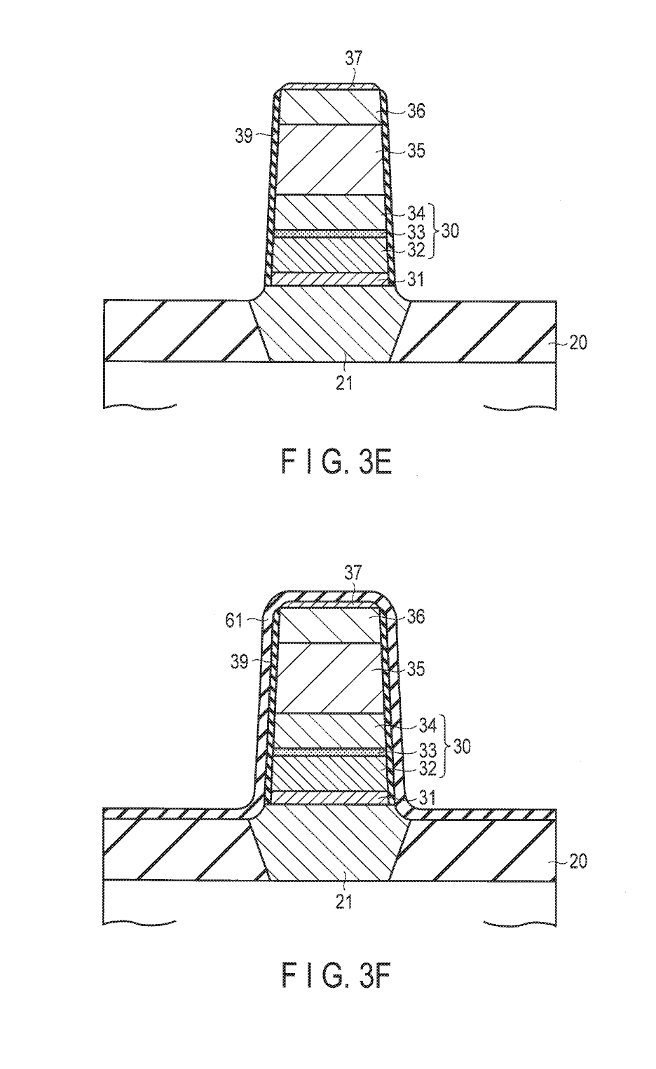

Next, a method of manufacturing the memory cell portion of FIG. 2 will be described with reference to FIGS. 3A to 3F.

First, as shown in FIG. 3A, the base substrate provided with the MOS transistor having a buried gate structure and functioning as a switch is prepared on the surface of the Si substrate 10. The base substrate is formed in the following manner. For example, a trench is formed on the surface of the Si substrate 10, and then the gate insulating film 11 of SiO₂ or the like is formed on the bottom and side surfaces of the trench by thermal oxidation. Then, the gate electrode 12 formed of a conductive film of poly-Si or the like is buried in such a manner as to fill the trench halfway. Subsequently, the insulating film 13 of SiN or the like is buried in the trench in such a manner as to flatten the surface.

Note that the gate electrode 12 is not necessarily formed of a semiconducting material and may be formed of metal such as W. Further, it is also possible to use barrier metal such as TiN. Still further, it is also possible to form a source and drain region by scattering p- and n-type impurities in the surface portion of the Si substrate 10.

Next, the first interlayer insulating film 20 of SiO₂ or the like is deposited on the base substrate by the CVD method. Then, a contact hole is formed in the interlayer insulating film 20 by reactive ion etching (RIE) or the like to connect to the drain of the transistor, and then the bottom electrode (BEC) 21 is formed in such a manner as to be buried in the contact hole. More specifically, a conductive material composing the bottom electrode is deposited on the interlayer insulating film 20 by spattering or the like in such a manner as to fill the contact hole, and the conductive material film on the interlayer insulating film 20 is then removed by chemical mechanical polishing/planarization (CMP) in such a manner as to leave the conductive material only in the contact hole.

Here, to secure a sufficient contact area between the bottom electrode 21 and the MTJ element even when misaligned with each other, it is preferable that the exposed area of the bottom electrode 21 be greater than the bottom area of the MTJ element portion.

Next, as shown in FIG. 3B, a stacked layer structure for the MTJ element is formed on the bottom electrode 21 and the interlayer insulating film 20. That is, the buffer layer 31 is formed on the bottom electrode 21 and the interlayer insulating film 20, and then the storage layer 32 of CoFeB or the like is formed by sputtering. The tunnel barrier layer 33 of MgO is then formed on the storage layer 32. The reference layer 34 of CoFeB or the like is formed on the tunnel barrier layer 33, and the shift-adjustment layer 35 and the cap layer 36 are formed thereon.

Then, as shown in FIG. 3C, a hard mask (mask material layer) 37 corresponding to the MTJ element pattern is formed on the cap layer 36. The hard mask 37 may be metal material or may be an insulating material.

Subsequently, as shown in FIG. 3D, the stacked layer structure is selectively etched from the cap layer 36 to the buffer layer 31 by ion beam etching (IBE) using, for example, argon (Ar) to reach the bottom electrode 21. That is, the stacked layer structure is selectively etched by using the hard mask 37. By etching the stacked layer structure, the MTJ element portion including the MTJ element 30 is formed, and the sidewall film 38 is further formed on the sidewall of the MTJ element portion. Note that the hard mask 37 may slightly remain or may be completely removed at the end of etching.

Note that the inert gas used for ion beam etching is not necessarily Ar, but may be xenon (Xe), krypton (Kr), neon (Ne) or the like.

Here, to complete the MTJ element portion, it is necessary to etch down the structure deeper than the buffer layer 31, that is, to over-etch the structure. In the over-etching process, the material composing the bottom electrode 21 mixes with the materials produced by the MTJ etching process, and the mixture is attached to the sidewall of the MTJ element portion. If the oxidation-resistant conductive material of the bottom electrode in the mixture is attached to the sidewall of the MTJ element 30, a short circuit is caused between the storage layer 32 and the reference layer 34 of the MTJ element 30, and consequently the MTJ element 30 will not function as a memory element.

To secure a sufficient margin of lithographic exposure between the bottom electrode 21 and the MTJ element 30, the surface of the bottom electrode 21 has an area greater than that of the bottom surface of the MTJ element portion. Consequently, a part of the bottom electrode 21 is inevitably etched in the over-etching process.

The degree of failure done by a short circuit which the sidewall film 38 causes between the storage layer 32 and the reference layer 34 via the MgO end surface is defined by the shunt failure rate (SFR). To prevent a short circuit in the MTJ element 30, it is necessary to decrease the SFR by removing or oxidizing the sidewall film 38. Here, in the case of using the oxidation-resistant conductive material for the bottom electrode 21, SF prevention cannot be achieved without a vigorous oxidation process. Therefore, in the present application, oxidation processing is preformed on the sidewall film 38 by oxidation processing using oxygen radicals. By the processing, as shown in FIG. 3E, the sidewall insulating film 39 is formed on the sidewall of the MTJ element portion.

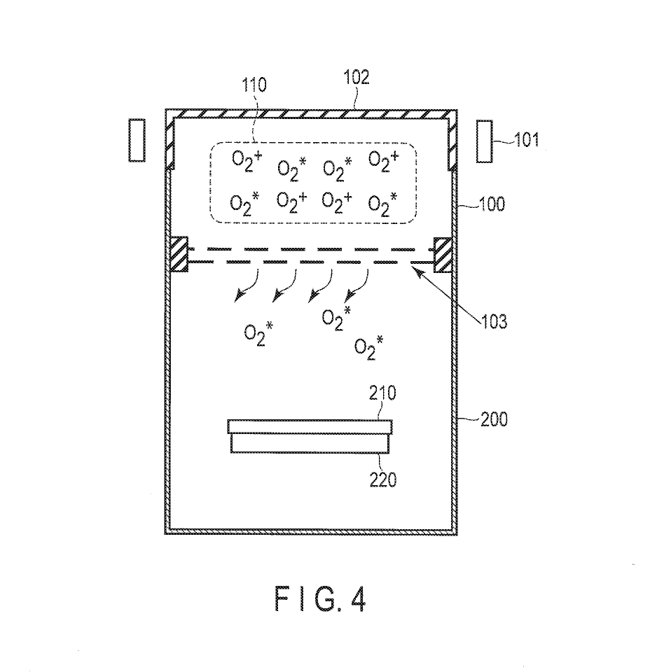

FIG. 4 is an overview configuration diagram showing an oxidation process unit used in the present embodiment. Oxygen is activated in a first chamber 100 by plasma and then introduced into a second chamber 200. More specifically, gaseous O₂ is introduced into the first chamber 100, and plasma 110 is generated in the chamber 100 by using microwaves or by electric discharge. Then, among the oxygen ions (O₂⁺) and oxygen radicals (O₂*) in the plasma 110, only the oxygen radials are selectively introduced into the chamber 200 through a shower ring. Further, the chamber 200 is provided with a stage 220 which mounts a sample (wafer which mounts [is provided with] the MTJ element) 210. Note that the elements denoted by the reference numbers 101, 102 and 103 are respectively an RF antenna, an RF window of SiO₂ and the shower ring.

In this unit, radical oxidation can be performed by placing a sample such as that shown in FIG. 3D in the second chamber 200. By performing radical oxidation, the conductive sidewall film 38 becomes the sidewall insulating film 39 as shown in FIG. 3E.

If necessary, a protective insulating film 61 of SiN or the like is further formed on the sidewall of the MTJ element portion as shown in FIG. 3F to protect the MTJ element portion.

After that, the structure of FIG. 2 is obtained by forming the second interlayer insulating film 40, forming the contact plugs 41 and 42, and then forming the interconnects 51 and 52.

As described above, the present embodiment features in selectively etching the stacked layer structure for the MTJ element portion and then oxidizing the sidewall film 38 attached to the side surface of the MTJ element portion by using oxygen radicals.

Here, the methods of oxidizing the sidewall film 38 include oxidation using low-pressure gaseous oxygen having a pressure lower than the atmospheric pressure, atmospheric oxidation, radical oxidation, plasma oxidation and various other oxidation methods. Here, the atmospheric oxidation is to naturally oxidize the film by leaving it in the atmosphere. The oxidation methods in ascending order of oxidation vigor are oxidation using low-pressure gaseous oxygen, atmospheric oxidation, radical oxidation and plasma oxidation.

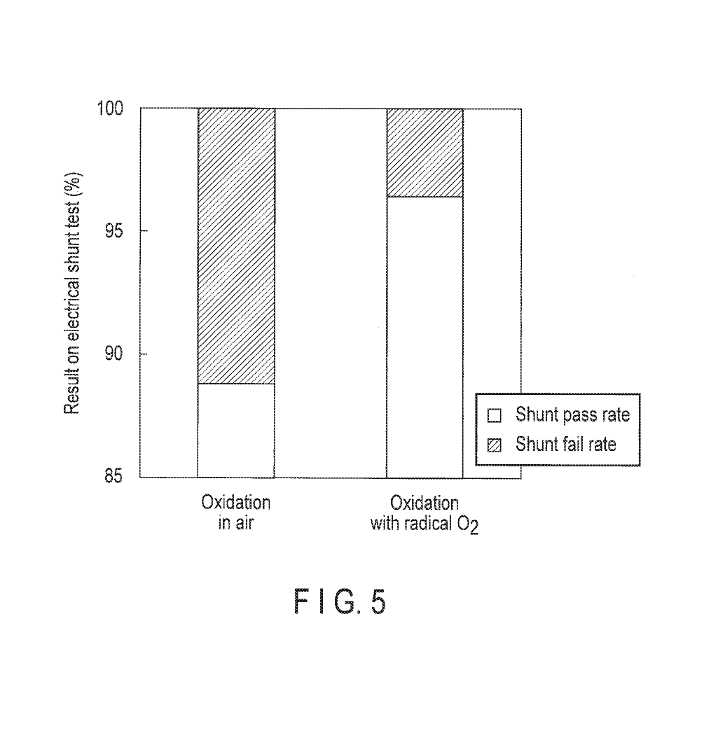

FIG. 5 shows the SFR distribution in the case of oxidizing the sidewall film 38 by means of atmospheric oxidation and the SFR distribution in the case of oxidizing the sidewall film 38 by means of radical oxidation.

As shown in FIG. 5, in the case of atmospheric oxidation, a portion of the wafer having a normal SFR is less than 90%. Therefore, the manufacturing yield of the MTJ element decreases. In oxidation using low-pressure gaseous oxygen, the SFR is worse. This is because the oxidation is not vigorous enough to sufficiently oxidize the sidewall film 38.

On the other hand, in the case of radical oxidation, a portion of the wafer having a normal SFR is greater than 95%. This is because the sidewall film 38 is sufficiently oxidized by radical oxidation. Therefore, the manufacturing yield of the MTJ element can be improved by performing radical oxidation.

Note that, in the case of oxidizing the sidewall film 38 by means of plasma oxidation, which is the most vigorous oxidation method, the SFR further improves but this leads to degradation in the magnetic characteristics of the MTJ element 30. This is because plasma oxidation is so vigorous that oxidation proceeds not only to the sidewall but also to the inner portion of the MTJ element 30. In radical oxidation, on the other hand, oxidation is kept to the sidewall of the MTJ element 30 and the degradation of the magnetic characteristics hardly increases.

As described above, according to the present embodiment, it is possible to reduce the SFR without degradation of the magnetic characteristics of the MTJ element 30 by selectively etching the stacked layer structure for the MTJ element 30 by IBE and then oxidizing the sidewall film 38 by radical oxidation. Consequently, the element characteristics and the manufacturing yield can be improved.

### Second Embodiment

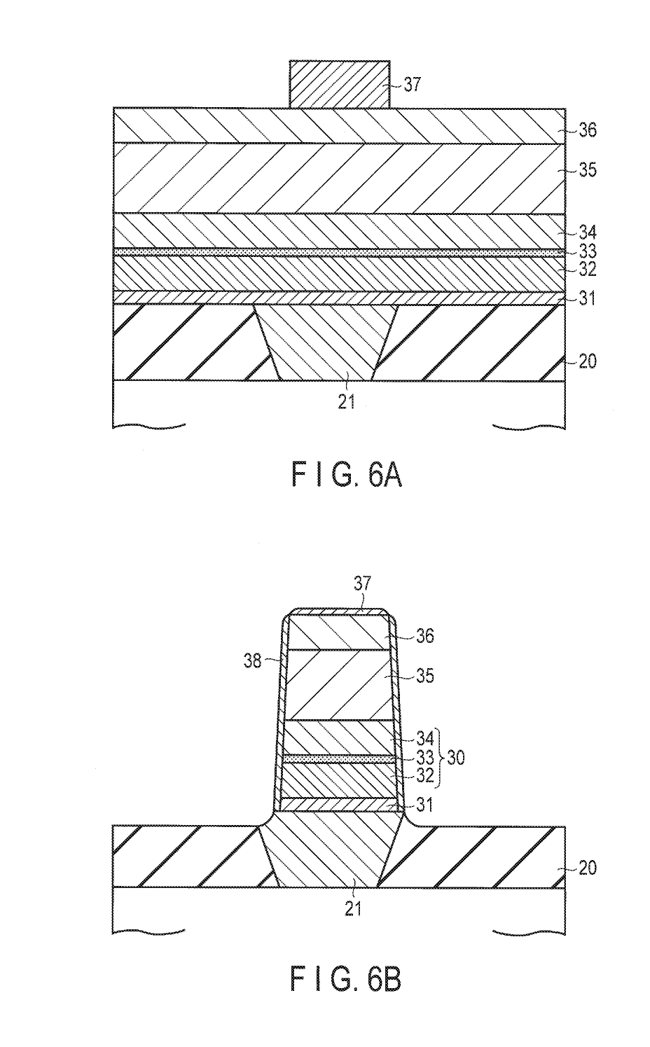

FIGS. 6A and 6B are cross-sectional diagrams showing the manufacturing procedure of a magnetoresistive memory device of a second embodiment. Note that the portions the same as those in FIGS. 3A to 3F are denoted by the same reference numbers and descriptions thereof will be omitted.

In the above-described first embodiment, since the bottom electrode 21 (exposed area of the surface) is greater than the MTJ element portion (area of the bottom surface), the bottom electrode 21 is etched in the over-etching process, and the etching product of the bottom electrode 21 is attached to the sidewall of the MTJ element portion. In a case where the bottom electrode 21 has an area substantially the same as that of the MTJ element portion, not the bottom electrode 21 but the interlayer insulating film 20 is etched even in the over-etching process. In this way, it is possible to prevent the material of the bottom electrode 21 from attaching to the sidewall of the MTJ element portion.

However, as shown in FIG. 6A, there is a case where the bottom electrode 21 and the MTJ element portion are misaligned with each other.

In that case, when the stacked layer structure is selectively etched by IBE using the hard mask 37, the bottom electrode 21 will be exposed on one side of the MTJ element portion as shown in FIG. 6B. Therefore, the bottom electrode 21 is etched in the over-etching process, and the etching product of the bottom electrode 21 is thereby attached to the sidewall of the MTJ element portion.

In the state of FIG. 6B, if the sidewall film 38 is oxidized by radical oxidation in a manner similar to that of the first embodiment, it is possible to reduce the SFR without degradation of the magnetic characteristics. Therefore, an effect similar to that produced by the first embodiment can be obtained.

Note that, if the exposed area of the bottom electrode 21 is less than the bottom area of the MTJ element portion, the bottom electrode 21 will not be exposed in the over-etching process even when the bottom electrode 21 is misaligned with the MTJ element portion to some extent. However, in that case, the contact area between the bottom electrode 21 and the MTJ element portion decreases, and this is not desirable in light of the element characteristics. Therefore, it is preferable that the bottom electrode 21 has an area greater than or equal to that of the MTJ element portion. In a case where the bottom electrode 21 has an area greater than or equal to that of the MTJ element portion in light of the element characteristics, radical oxidation of the sidewall film of the present embodiment is highly effective.

### Third Embodiment

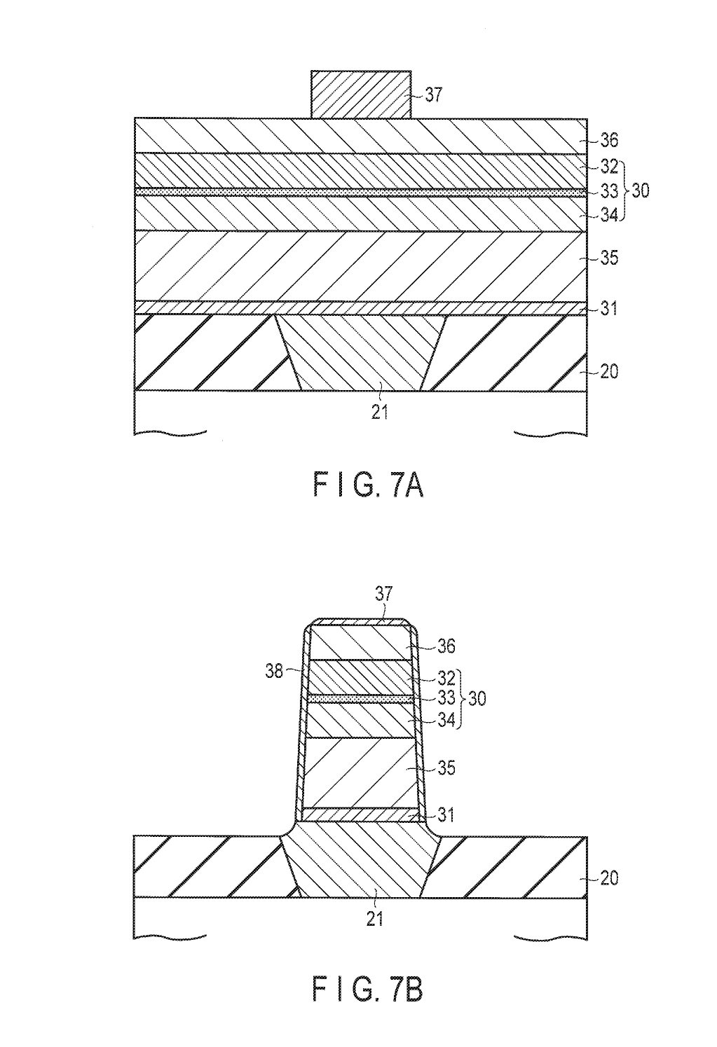

FIGS. 7A and 7B are cross-sectional diagrams showing the manufacturing procedure of a magnetoresistive memory device of the third embodiment. Note that the portions the same as those in FIGS. 3A to 3F are denoted by the same reference numbers and descriptions thereof will be omitted.

The present embodiment is different from the first embodiment in that the storage layer 32 and the reference layer 34 of the MTJ element 30 have the vertically opposite positional relationship.

As shown in FIG. 7A, on the bottom electrode 21 and the interlayer insulating film 20, the buffer layer 31, the shift-adjustment layer 35, the storage layer 34, the tunnel barrier layer 33, the storage layer 32 and the cap layer 36 are formed. On the cap layer 36, the hard mask 37 corresponding to the MTJ element pattern is formed.

Then, as shown in FIG. 7B, the stacked layer structure is selectively etched from the cap layer 36 to the buffer layer 31 by IBE using, for example, Ar to reach the bottom electrode 21.

Also in this etching process, the material of the bottom electrode 21 and the material of the buffer layer 31 are attached to the sidewall of the MTJ element portion in a manner similar to that of the first embodiment. Therefore, the sidewall film 38 is oxidized by oxidation processing using oxygen radicals in a manner similar to that of the first embodiment.

After then, the structure of the memory cell portion is complete by forming the interlayer insulating film 40, forming the contact plugs 41 and 42, and then forming the interconnects 51 and 52 in a manner similar to that of the first embodiment.

Also in the present embodiment, it is possible to reduce the SFR without degradation of the magnetic characteristics of the MTJ element 30 by selectively etching the stacked layer structure for the MTJ element 30 by IBE and then oxidizing the sidewall film 38 by radical oxidation. Therefore, an effect similar to that produced by the first embodiment can be obtained.

### (Modification)

Note that the present invention will not be limited to each of the embodiments described above.

The oxidation process unit, although taking the form of introducing oxygen radicals selectively from plasma, may be appropriately modified in accordance with specifications. Further, radical oxidation is not necessarily performed under the conditions described in the embodiments but may be appropriately performed on condition that the sidewall is sufficiently oxidized and the tunnel barrier layer is hardly oxidized.

Although the shift-adjustment layer has been assumed to be provided above or below the MTJ element in the embodiments, the shift-adjustment layer can be omitted in a case where the influence of a leakage magnetic field from the reference layer can be neglected.

The bottom electrode may be formed of any material which is not sufficiently oxidized by low-pressure oxidation or atmospheric oxidation but is sufficiently oxidized by radical oxidation when formed on the sidewall of the MTJ element portion as an etching product. The material may be W, Ta, Ru, Ti, TaN or TiN.

The selective etching process of the stacked layer structure is not necessarily performed by IBE and may be performed by RIE instead. In any etching processes which produce an etching product to be attached to an etched sidewall, it is highly effective to perform radical oxidation after the etching process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a magnetoresistive memory device comprising:
forming a base substrate including a conductive electrode exposed at a part of a surface;
forming a stacked layer structure on the base substrate;
etching the stacked layer structure to form the magnetoresistive element on the electrode; and
exposing the magnetoresistive element to an atmosphere of oxygen radicals.

2. The method of claim 1, wherein
the electrode is exposed by the etching of the stacked layer structure.

3. The method of claim 2, wherein
the etching of the stacked layer structure includes attaching an etching product to a sidewall of the magnetoresistive element.

4. The method of claim 3, wherein
the etching product is oxidized by exposing the magnetoresistive element to the atmosphere of oxygen radicals.

5. The method of claim 1, wherein
the etching of the stacked layer structure includes forming a mask material layer corresponding to a pattern of the magnetoresistive element on the stacked layer structure, selectively etching the stacked layer structure by using the mask material layer as a mask, and then selectively etching a part of the electrode.

6. The method of claim 1, wherein
the stacked layer structure comprises a layered portion which includes a first magnetic layer, a second magnetic layer, and a nonmagnetic layer between the first and second magnetic layers.

7. The method of claim 6, wherein
the first magnetic layer is a storage layer having a variable direction of magnetization, the second magnetic layer is a reference layer having a fixed direction of magnetization, and the nonmagnetic layer is a tunnel barrier layer.

8. The method of claim 7, wherein
the stacked layer structure comprises a shift-adjustment layer provided on a side of the reference layer of the layered portion opposite to that provided with the tunnel barrier layer and having a direction of magnetization opposite to that of the reference layer.

9. The method of claim 6, wherein
the stacked layer structure comprises a conductive cap layer on the layered portion.

10. The method of claim 6, wherein
the forming of the stacked layer structure includes forming a buffer layer on the base substrate and forming the layered portion on the butter layer.

11. The method of claim 10, wherein
the electrode contains one of Ta, W and Mo, and the buffer layer contains one of Hf, W and AlN.

12. The method of claim 1, wherein
the forming of the base substrate includes forming a transistor functioning as a switch on a semiconductor substrate, forming an interlayer insulating film on the semiconductor substrate provided with the transistor, forming a contact hole in the interlayer insulating film to connect to a part of the transistor, and burying a bottom electrode as the electrode in the contact hole.

13. The method of claim 4, wherein
the etching product is oxidized by supplying oxygen radicals activated in plasma.

14. The method of claim 4, further comprising
forming a sidewall protective film on the sidewall of the magnetoresistive element after the oxidizing of the etching product.

15. The method of claim 14, wherein
the sidewall protective film includes a silicon nitride film.

16. The method of claim 1, wherein
the electrode exposed at the surface of the substrate has an area greater than a bottom area of the stacked layer structure.

17. A method of manufacturing a magnetoresistive memory device, comprising:
forming a transistor functioning as a switch on a semiconductor device;
forming an interlayer insulating film on the semiconductor substrate provided with the transistor;
forming a contact hole in the interlayer insulating film to connect to a part of the transistor;
burying a bottom electrode in the contact hole;
forming a stacked layer structure including a layered portion on the interlayer insulating film and the bottom electrode, the layered portion includes a first magnetic layer, a second magnetic layer, and a nonmagnetic layer between the first and second magnetic layers;
forming a mask material layer corresponding to a pattern of a magnetoresistive element on the stacked layer structure;
processing the stacked layer structure into the pattern of the magnetoresistive element by using the mask material layer as a mask and selectively etching the stacked layer structure; and
exposing the magnetoresistive element formed by the processing of the stacked layer structure to an atmosphere of oxygen radicals.

18. The method of claim 17, wherein
the processing of the stacked layer structure into the pattern of the magnetoresistive element includes selectively etching the stacked layer structure and further selectively etching a part of the electrode by ion beam etching using an inert gas.

19. The method of claim 17, wherein
the exposing of the magnetoresistive element to the atmosphere of oxygen radicals includes oxidizing an etching product produced by the etching and attached to a sidewall of the magnetoresistive element.

20. The method of claim 19, wherein
the etching product is oxidized by supplying oxygen radicals activated in plasma.
